(19) United States
(12) Patent Application Publication
(10) Pub. No.: US 2026/0332153 A1
(43) Pub. Date: Oct. 22, 2026

(54) PHASE-LOCKED LOOP CIRCUIT AND METHOD OF CONTROLLING THE SAME

(71) Applicant: Hanwha Solutions Corporation, Seoul (KR)

(72) Inventors: Yeong Jin KIM, Seoul (KR); Jong Won SONG, Seoul (KR); Young Chae KIM, Seoul (KR); Gi Yob PARK, Seoul (KR); Seong Hoon HA, Seoul (KR); Seong Hun LEE, Seoul (KR)

(73) Assignee: Hanwha Solutions Corporation, Seoul (KR)

(21) Appl. No.: 19/552,752

(22) Filed: Feb. 27, 2026

(30) Foreign Application Priority Data
Apr. 22, 2025 (KR) 10-2025-0052344

(51) Int. Cl. H03L 7/093; H02J 3/38; H02J 101/24

(52) U.S. Cl. CPC H03L 7/093; H02J 3/381; H02J 2101/24

(57) ABSTRACT

A method of controlling a phase-locked loop (PLL) circuit includes generating a virtual two-phase signal based on a single-phase alternating-current signal that has passed through a band-pass filter, extracting a phase angle of the single-phase alternating-current signal based on the virtual two-phase signal, and updating a cutoff frequency of the band-pass filter based on the phase angle.

### CROSS-REFERENCE TO RELATED APPLICATION

This application is based on and claims priority under 35 U.S.C. § 119 to Korean Patent Application No. 10-2025-0052344, filed on Apr. 22, 2025, in the Korean Intellectual Property Office, the disclosure of which is incorporated by reference herein in its entirety.

### BACKGROUND

### 1. Field

The present disclosure relates to a phase-locked loop circuit and a method of controlling the same. More particularly, the present disclosure relates to a phase-locked loop circuit including an adaptive band-pass filter, and a method of controlling the same.

### 2. Description of the Related Art

Phase-locked loop (PLL) is one of the key techniques in inverter control, serving to synchronize the output voltage of an inverter with the voltage of a grid. Here, in order for a PLL to stably control the inverter, it is necessary to accurately sense an alternating-current (AC) voltage of the grid.

However, when the sensed voltage signal contains noise or a direct-current (DC) offset, the performance of the PLL may be degraded. This may cause unstable frequency synchronization of the inverter and degrade the quality of the output voltage of the inverter.

In particular, in a grid-tied environment in which the inverter is connected to the grid in real time, the performance of the PLL directly affects power quality. Although existing PLL algorithms incorporate a certain level of noise filtering capability, there remains a high likelihood of errors occurring under extreme conditions or during abnormal voltage fluctuations.

Accordingly, the development of PLL technology robust against noise and DC offset is a critical factor for improving inverter stability and performance. To this end, it is necessary to apply more precise signal processing techniques and enhanced filtering technologies to the PLL, thereby minimizing signal distortion occurring during a sensing process. In addition, it is required that the PLL achieve accurate and rapid phase tracking under various environmental conditions.

The foregoing background art is technical information that the inventor possessed for deriving the present disclosure or acquired in the course of deriving the present disclosure, and does not necessarily constitute prior art disclosed to the general public prior to the filing of the present disclosure.

### SUMMARY

The present disclosure provides a phase-locked loop circuit and a method of controlling the same. Technical objectives of the present disclosure are not limited to the foregoing, and other unmentioned objects or advantages of the present disclosure would be understood from the following description and be more clearly understood from the embodiments of the present disclosure. In addition, it would be appreciated that the objectives and advantages of the present disclosure may be implemented by means provided in the claims and a combination thereof.

A first aspect of the present disclosure may provide a method of controlling a phase-locked loop (PLL) circuit, the method including generating a virtual two-phase signal based on a single-phase alternating-current signal that has passed through a band-pass filter, extracting a phase angle of the single-phase alternating-current signal based on the virtual two-phase signal, and updating a cutoff frequency of the band-pass filter based on the phase angle.

A second aspect of the present disclosure may provide a PLL circuit including a band-pass filter configured to pass a single-phase alternating-current signal, a proportional-integral (PI) controller configured to extract a phase angle of the single-phase alternating-current signal based on a virtual two-phase signal, and a processor configured to update a cutoff frequency of the band-pass filter based on the phase angle.

A third aspect of the present disclosure may provide a computer-readable recording medium having recorded thereon a program for causing a computer to execute the method according to the first aspect of the present disclosure.

Other aspects, features, advantages other than those described above will become apparent from the following drawings, claims, and detailed description of the present disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is an exemplary diagram for schematically describing a power supply system;

FIG. 2 illustrates an example of a power supply system according to an embodiment;

FIG. 3 illustrates an example of a power supply system according to another embodiment;

FIG. 4 illustrates an example of a power supply system according to another embodiment;

FIG. 5 is a flowchart of a method of controlling a phase-locked loop (PLL) circuit, according to an embodiment;

FIG. 6 is an example of a block diagram illustrating a method of controlling a PLL circuit, according to an embodiment;

FIG. 7 is an example of a block diagram illustrating a method of extracting a phase angle, according to an embodiment;

FIG. 8 is an example of a block diagram illustrating a method of controlling a PLL circuit, according to another embodiment;

FIG. 9 illustrates an example of a method of detecting a first frequency by using zero-crossing points, according to an embodiment; and

FIG. 10 is a block diagram of a PLL circuit according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Advantages and features of the present disclosure and a method for achieving them will be apparent with reference to embodiments of the present disclosure described below together with the accompanying drawings. The present disclosure may, however, be embodied in many different forms and should not be construed as being limited to the embodiments set forth herein, and all changes, equivalents, and substitutes that do not depart from the spirit and technical scope of the present disclosure are encompassed in the present disclosure. These embodiments are provided such that the present disclosure will be thorough and complete, and will fully convey the concept of the present disclosure to those of skill in the art. In describing the present disclosure, detailed explanations of the related art are omitted when it is deemed that they may unnecessarily obscure the gist of the present disclosure.

Terms used herein are for describing particular embodiments and are not intended to limit the scope of the present disclosure. Singular expressions include plural expressions unless the context clearly indicates otherwise. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Some embodiments of the present disclosure may be represented by functional block components and various processing operations. Some or all of the functional blocks may be implemented by any number of hardware and/or software elements that perform particular functions. For example, the functional blocks of the present disclosure may be embodied by at least one microprocessor or by circuit components for a certain function. In addition, for example, the functional blocks of the present disclosure may be implemented by using various programming or scripting languages. The functional blocks may be implemented by using various algorithms executable by one or more processors. In addition, the present disclosure may employ known technologies for electronic settings, signal processing, and/or data processing. Terms such as “mechanism”, “element”, “unit”, or “component” are used in a broad sense and are not limited to mechanical or physical components.

In addition, connection lines or connection members between components illustrated in the drawings are merely exemplary of functional connections and/or physical or circuit connections. Various alternative or additional functional connections, physical connections, or circuit connections between components may be present in a practical device.

Hereinafter, the present disclosure will be described in detail with reference to the accompanying drawings.

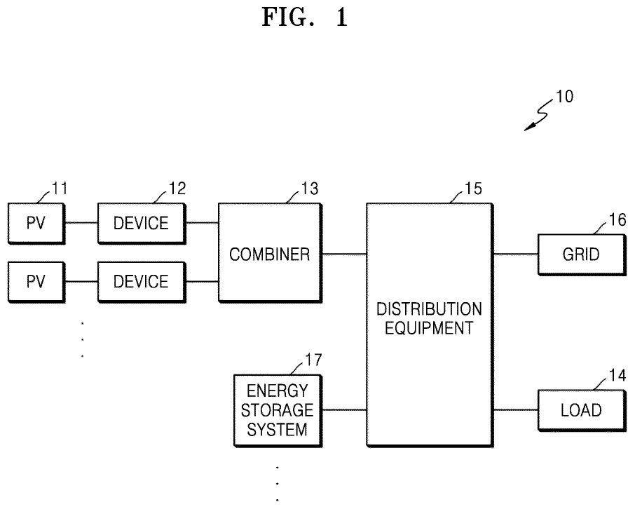

FIG. 1 is an exemplary diagram for schematically describing a power supply system.

Referring to FIG. 1, a power supply system 10 may include a device 12 or distribution equipment 15. Here, the device 12 may be an apparatus for converting power generated by a photovoltaic module 11. In some embodiments, the power supply system 10 may further include the photovoltaic module 11 or a combiner 13. In some embodiments, the power supply system 10 may be connected to a load 14 or a grid 16.

At least one photovoltaic module 11 may be installed on a roof or an outer wall of a building to generate power. For example, a plurality of photovoltaic modules 11 may be connected to each other to form a photovoltaic module array.

The at least one photovoltaic module 11 may be connected to the device 12. For example, at least one device 12 may be connected to each photovoltaic module 11. For example, when one device 12 is connected to each photovoltaic module 11, the number of devices 12 constituting the power supply system 10 may be equal to the number of photovoltaic modules 11.

The device 12 may be a power conditioning system (PCS), also known as a power conversion system, that performs power conversion on power generated by the photovoltaic module 11. For example, the device 12 may perform a predetermined conversion on the power generated by the photovoltaic module 11. In addition, the device 12 may supply the converted power to another apparatus (e.g., the grid 16 or the load 14).

In some embodiments, the device 12 may be a module-level power electronics (MLPE) device. For example, the device 12 may be an optimizer or a microinverter (MI).

For example, when the device 12 is an optimizer, the device 12 may regulate power produced by the photovoltaic module 11 and output the regulated power to an inverter (e.g., a string inverter). Current converted by the inverter (e.g., from direct current (DC) to alternating current (AC)) may be output to the grid 16 or the load 14.

As another example, when the device 12 is an MI, the device 12 may convert power generated by the photovoltaic module 11 (e.g., from DC to AC). The current converted by the device 12 may be output to the grid 16 or the load 14.

Here, the device 12 may receive a voltage signal from the grid 16. In detail, the device 12 may receive information about the phase and frequency of the voltage of the grid 16. Based on the received information about the phase and frequency, the device 12 may synchronize its output power with the voltage of the grid 16.

In some embodiments, the power supply system 10 may further include the combiner 13. For example, some of the plurality of devices 12 may be connected to the distribution equipment 15 via the combiner 13. For example, power output from the plurality of devices 12 may be combined into a single output at the combiner 13 and then supplied to the distribution equipment 15.

In some embodiments, the device 12 and the distribution equipment 15 may be connected via a power path that does not include the combiner 13. Alternatively, at least one device 12 may be connected to the distribution equipment 15 via a power path that does not include the combiner 13, while at least one other device 12 may be connected to the distribution equipment 15 via the combiner 13.

The combiner 13 may perform control of voltage, current, and/or power output from the device 12 based on a power supply state of the photovoltaic module 11, the device 12, and/or the grid 16. In addition, the distribution equipment 15 may receive an abnormality signal from the device 12 and set an operation mode of the combiner 13 to a diagnosis mode, a driving mode, or the like.

In some embodiments, the combiner 13 may include an energy management system (EMS). The EMS may control various operations of the combiner 13. For example, the EMS may perform control of any one of voltage, current, and power supplied to or output from the combiner 13, according to a power supply state of any one of the photovoltaic module 11, the device 12, and the grid 16. In addition, the EMS may transmit a control signal to the combiner 13 to set the operation mode of the combiner 13 to the diagnosis mode, the driving mode, or the like.

The load 14 may refer to an object installed at an electrical consumer, such as a residence, a commercial facility, or a factory, and that operates by receiving at least one of energy generated by the photovoltaic module 11, energy stored in an energy storage system 17, and energy supplied from the grid 16. For example, when the electrical consumer receiving power is a residence, the load 14 may include home appliances such as a washing machine, a refrigerator, or a television (TV).

The grid 16 may include an infrastructure system for generating, transmitting, and distributing power. For example, the grid 16 may include an infrastructure system such as a power plant, a substation, or a power line network. In some embodiments, the grid 16 may deliver electrical energy generated at a power plant to the power supply system 10, or deliver surplus power generated by the power supply system 10 to the outside of the power supply system 10.

For example, commercial power may be transmitted from the grid 16 through utility poles. In addition, commercial power may be supplied to an electricity consumer through a transformer. In some embodiments, the power supply system 10 may be implemented as an off-grid system that is not connected to the grid 16.

In some embodiments, the power supply system 10 may further include at least one energy storage system 17. For example, the power supply system 10 may include a plurality of energy storage systems 17. The energy storage system 17 may receive and store power generated by the photovoltaic module 11 and/or power delivered from the grid 16. The energy storage system 17 may store electrical energy and supply the electrical energy to the load 14 when required by the load 14.

The energy storage system 17 may include a battery that stores power and a power conversion module. The battery may include a battery management system (BMS) configured to monitor a state of charge (SoC), a state of health (SoH), a voltage, and/or a current of the battery, perform diagnosis on the battery, and perform safety functions such as current interruption.

In some embodiments, the power conversion module may be a PCS configured to perform conversion between battery-side power and opposite-side power. For example, the PCS may perform conversion between battery-side DC and opposite-side AC. For example, the PCS may include a bidirectional DC-DC converter connected to the battery and configured to convert a voltage, and a bidirectional inverter connecting the DC-DC converter to the outside of the energy storage system 17.

In some embodiments, the energy storage system 17 may further include an EMS. In this case, the EMS may control the operation of the energy storage system 17. In some embodiments, the energy storage system 17 may further include at least one battery (not shown).

The EMS may perform control of voltage, current, or power according to a power supply state of the battery and/or the grid 16. Here, each of the voltage, the current, or the power may be supplied to or output from the energy storage system 17. In addition, the EMS may set the operation mode of the energy storage system 17 to a diagnosis mode, a driving mode, or the like.

For example, the EMS may be coupled to a certain component of the power supply system 10. Here, the EMS may control the operation of the component coupled to the EMS. In some embodiments, the EMS may control the operation of another component of the power supply system 10 that is not coupled to the EMS. For example, when the EMS is coupled to the combiner 13, the EMS may control the operation of another component included in the power supply system 10 as well as the operation of the combiner 13. As another example, when the EMS is coupled to the energy storage system 17, the EMS may control the operation of another component included in the power supply system 10 as well as the operation of the energy storage system 17.

In some embodiments, components of the power supply system 10 may be electrically connected to each other via the distribution equipment 15. In addition, the distribution equipment 15 may control a power flow of the power supply system 10. For example, the distribution equipment 15 may electrically connect the photovoltaic module 11 to the load 14. For example, the distribution equipment 15 may be connected to the device 12 to electrically connect the photovoltaic module 11 to the load 14. In some embodiments, the distribution equipment 15 may be further connected to at least one of the energy storage system 17 and the grid 16. In this case, the distribution equipment 15 may obtain information about the phase and frequency of the voltage of the grid 16 and transmit the obtained information to the device 12.

For example, the distribution equipment 15 may be a distribution panel that distributes power within the power supply system 10. For example, the distribution equipment 15 may be a master service panel (MSP) that distributes power generated by the photovoltaic module 11 to the load 14 and the like.

As another example, the distribution equipment 15 may be a main controller that distributes power within the power supply system and controls each device 12. For example, the main controller may include a switch, a breaker, and a control unit. The switch, the breaker, and the control unit may be implemented as independent devices, respectively, or at least some of the switch, the breaker, and the control unit may be included in a single device.

The main controller may include a switch that controls electrical connections between components connected to the main controller. The components connected to the main controller may include, for example, at least one device 12, the load 14, and the like. For example, the main controller may include a device that provides or cuts off an electrical connection to each component of the power supply system 10 according to an operation state of the component. Here, the device that provides or cuts off an electrical connection may be a relay, a power semiconductor, or the like. The relay, power semiconductor, or the like may provide or cut off an electrical connection according to an operation state of each device 12 or each energy storage system 17.

The main controller may perform a rapid shutdown to stop power generation of the photovoltaic module 11 in an emergency situation, such as when overcurrent occurs in the power supply system 10. To this end, the main controller may include a breaker that cuts off a connection between the device 12 and the load 14.

The main controller may include a control unit that controls the overall operation of the main controller. The control unit may control the operation of other components of the power supply system 10 (e.g., the device 12 or the energy storage system 17) in addition to the main controller.

The control unit may perform control of voltage, current, or power according to a power supply state of the photovoltaic module 11, the device 12, the combiner 13, the load 14, the grid 16, or the energy storage system 17. The voltage, current, or power to be controlled may be output from or supplied to each component. In addition, the control unit may set an operation mode of the main controller, the device 12, or the energy storage system 17 to a diagnosis mode, a driving mode, or the like.

For example, the control unit may control the photovoltaic module 11, the device 12, the combiner 13, or the energy storage system 17, based on a state of the power supply system 10. For example, the control unit may control other components (e.g., the device 12) of the power supply system 10 by causing the main controller to perform communication with the other components of the power supply system 10. The communication between the main controller and the other components of the power supply system 10 may be performed by using a power-line communication (PLC) method, but is not limited thereto.

For example, the control unit may control the device 12 according to a power generation state of the photovoltaic module 11. For example, the main controller may receive a control command from a server that monitors the power generation state of the photovoltaic module 11, and the control unit may control the device 12 according to the control command.

When the power supply from the grid 16 is unstable (e.g., in an off-grid situation), the main controller may supply power to at least some of the loads 14. For example, when the power supply from the grid 16 is unstable, the main controller may preferentially supply power to a backup load having a relatively high need for stable power supply. Here, the main controller may preferentially supply power generated by the photovoltaic module 11 or power stored in the energy storage system 17 to the backup load.

In some embodiments, the power supply system 10 may further include an auxiliary power generation device (e.g., a diesel generator) that generates power by a method other than photovoltaic power generation. For example, an auxiliary power generation device may be further connected to the distribution equipment 15. When the photovoltaic module 11 and the energy storage device 17 alone cannot support the backup load due to environmental factors such as time of day or weather, the main controller may supply power generated by the auxiliary power generation device to the backup load.

The control unit may be implemented by at least one processor. The processor may process instructions of a computer program by performing basic arithmetic, logic, and input/output operations. Here, the instructions may be provided from an internal memory of the main controller, or from an external device. In addition, the processor may control the overall operation of other components included in the main controller.

In addition, the processor may perform at least a part of data analysis, processing, and result information generation for performing the above-described operations, by using at least one of machine learning, a neural network, or a deep learning algorithm, as a rule-based or artificial intelligence algorithm. The neural network may include neural network models based on architectures such as a convolutional neural network (CNN), a deep neural network (DNN), or a recurrent neural network (RNN).

For example, the processor may be implemented as an array of a plurality of logic gates, or may be implemented as a combination of a general-purpose microprocessor and a memory storing a program executable by the microprocessor. For example, the processor may include a general-purpose processor, a central processing unit (CPU), a microprocessor, a digital signal processor (DSP), a controller, a microcontroller, a state machine, and the like.

In some environments, the processor may include an application-specific integrated circuit (ASIC), a programmable logic device (PLD), a field-programmable gate array (FPGA), and the like. For example, the processor may refer to a combination of processing devices, such as a combination of a DSP and a microprocessor, a combination of a plurality of microprocessors, a combination of one or more microprocessors combined with a DSP core, or a combination of any other such configurations.

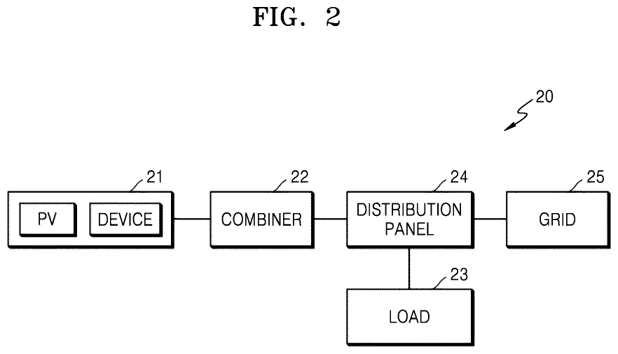

By combining at least some of the above-described components, the power supply system 10 may be implemented in various forms. Hereinafter, various embodiments of the power supply system 10 will be described with reference to FIGS. 2 to 4. However, the implementation of the power supply system 10 is not limited to the embodiments described below.

FIG. 2 illustrates an example of a power supply system according to an embodiment.

Referring to FIG. 2, a power supply system 20 according to an embodiment may include a photovoltaic power generation device 21, a combiner 22, and a distribution panel 24. In addition, the power supply system 20 may be connected to an external load 23 and an external grid 25. Here, the combiner 22, the load 23, and the grid 25 may correspond to the combiner 13, the load 14, and the grid 16, respectively. In addition, the distribution panel 24 may be the same as the distribution panel described above with reference to FIG. 1.

The photovoltaic power generation device 21 may be implemented to include the photovoltaic module 11 and the device 12 illustrated in FIG. 1. For example, the photovoltaic power generation device 21 may include a photovoltaic module provided with an MI, or a photovoltaic module provided with an optimizer. When the device is not figured to convert DC to AC, the photovoltaic power generation device 21 may further include a separate inverter that converts DC to AC.

The combiner 22 may electrically connect the photovoltaic power generation device 21 to the distribution panel 24. A plurality of photovoltaic power generation devices 21 may be connected to one combiner 22. For example, the combiner 22 may combine power output from the plurality of photovoltaic power generation devices 21 into a single output and then supply the combined power to the distribution panel 24.

Through this, the power supply system 20 may supply power to the load 23 or the grid 25. Here, the power supply system 20 may supply power generated by the photovoltaic power generation device 21 to the load 23 or the like via the distribution panel 24.

The combiner 22 may perform control of voltage, current, and/or power output from the photovoltaic power generation device 21 according to a power supply state of the photovoltaic power generation device 21, the load 23, and/or the grid 25. In addition, the distribution panel 24 may set an operation mode of the combiner 22 to a diagnosis mode, a driving mode, or the like.

In some embodiments, at least one photovoltaic power generation device 21 may be connected to the distribution panel 24 via a power path that does not include the combiner 22. For example, at least one photovoltaic power generation device 21 may be connected to the distribution panel 24 via a power path that does not include the combiner 22. In addition, at least one other photovoltaic power generation device 21 may be connected to the distribution panel 24 via the combiner 22.

In an embodiment, the power supply system 20 may further include a sub-panel (not shown) connected to the distribution panel 24. Here, at least one photovoltaic power generation device 21 may be connected to the sub-panel via the combiner 22, and at least one other photovoltaic power generation device 21 may be directly connected to the sub-panel.

By including the sub-panel that provides additional capacity, the power supply system 20 may increase a total amount of power generation of the photovoltaic power generation devices 21 that may be integrated into the power supply system 20.

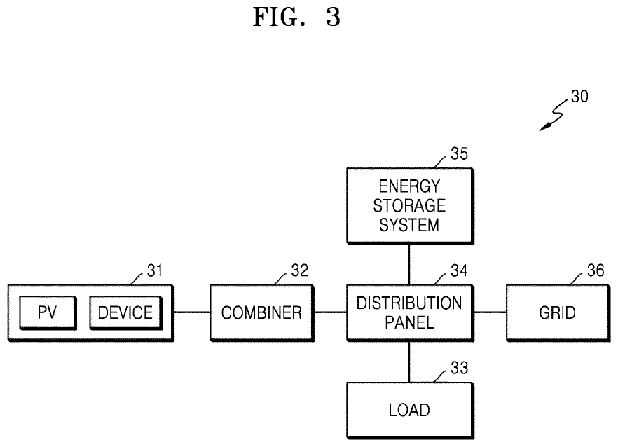

FIG. 3 illustrates an example of a power supply system according to another embodiment.

Referring to FIG. 3, a power supply system 30 according to an embodiment may include a photovoltaic power generation device 31, a combiner 32, a distribution panel 34, and an energy storage system 35. In addition, the power supply system 30 may be connected to a load 33 and a grid 36.

The power supply system 30 illustrated in FIG. 3 may correspond to the power supply system 20 illustrated in FIG. 2, further including at least one energy storage system 35. In an embodiment, the energy storage system 35 may be connected to the distribution panel 34 to be charged or discharged. In another embodiment, the energy storage system 35 may be connected to the combiner 32 to be charged or discharged.

Power stored in the energy storage system 35 included in the power supply system 30 may be used to support the load 33. In particular, when the load 33 cannot be supported only by the photovoltaic power generation device 31, power stored in the energy storage system 35 may be used to support the load 33. In addition, when power generated by the photovoltaic power generation device 31 exceeds an amount of power required to support the load 33, the excess may be stored in the energy storage system 35. In some embodiments, when a charge amount of the energy storage system 35 is below a threshold and the power generated by the photovoltaic power generation device 31 does not exceed the amount of power required to support the load 33, the energy storage system 35 may be charged with power supplied from the power grid 36.

Through this, the power supply system 30 may perform efficient power supply to the load 33 by using the energy storage system 35.

In some embodiments, the combiner 32 may perform control of voltage, current, or power output from the photovoltaic power generation device 31 according to a power supply state of the photovoltaic power generation device 31, the load 33, or the grid 36. In addition, the distribution panel 34 may set an operation mode of the combiner 32 to a diagnosis mode, a driving mode, or the like.

In addition, the energy storage system 35 may perform control of voltage, current, or power supplied to or output from the energy storage system 35 according to a power supply state of the photovoltaic power generation device 31, the load 33, or the grid 36. In some embodiments, the energy storage system 35 may include a BMS or an EMS. The BMS or EMS may set an operation mode of the energy storage system 35 to a diagnosis mode, a driving mode, or the like.

In an embodiment, the power supply system 30 may further include a sub-panel (not shown) connected to the distribution panel 34. In this case, at least one photovoltaic power generation device 31 may be connected to the sub-panel via the combiner 32, and at least one other photovoltaic power generation device 31 may be directly connected to the sub-panel.

In addition, at least one energy storage system 35 may be connected to the combiner 32, the distribution panel 34, or the sub-panel and integrated into the power supply system 30.

In some embodiments, at least one photovoltaic power generation device 31 may be connected to the distribution panel 34 via a power path that does not include the combiner 32. For example, at least one photovoltaic power generation device 31 may be connected to the distribution panel 34 via a power path that does not include the combiner 32. In addition, at least one other photovoltaic power generation device 31 may be connected to the distribution panel 34 via the combiner 32.

In an embodiment, at least one photovoltaic power generation device 31 may be connected to the sub-panel via the combiner 32. In addition, at least one other photovoltaic power generation device 31 may be directly connected to the sub-panel.

By including the sub-panel that provides additional capacity, the power supply system 30 may increase a total amount of power generation of the photovoltaic power generation devices 31 that may be integrated into the power supply system 30.

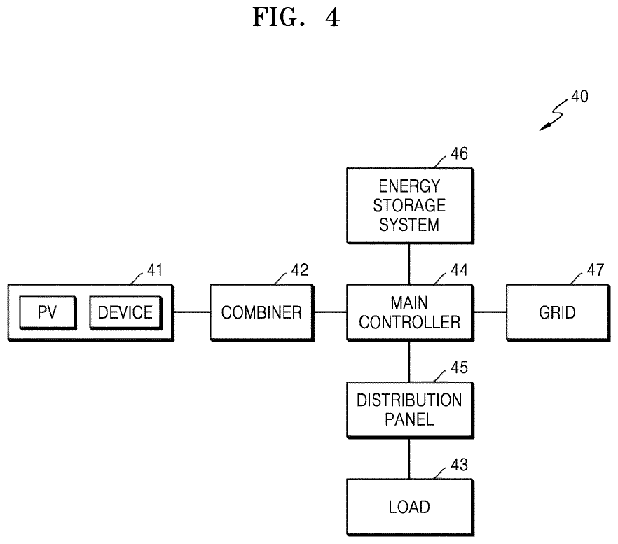

FIG. 4 illustrates an example of a power supply system according to another embodiment.

Referring to FIG. 4, a power supply system 40 according to an embodiment may include a photovoltaic power generation device 41, a combiner 42, a load 43, a main controller 44, a distribution panel 45, and an energy storage system 46. In addition, the power supply system 40 may be connected to an external grid 47.

Here, the photovoltaic power generation device 41, the combiner 42, the load 43, and the energy storage system 46 illustrated in FIG. 4 may correspond to the photovoltaic power generation device 31, the combiner 32, the load 33, and the energy storage system 35, respectively. In addition, the main controller 44 illustrated in FIG. 4 may correspond to the main controller described above with reference to FIG. 1.

The combiner 42 may electrically connect at least one photovoltaic power generation device 41 to the main controller 44. For example, the combiner 42 may combine power output from the at least one photovoltaic power generation device 41 into a single output and then supply the combined power to the main controller 44.

The main controller 44 may electrically connect the combiner 42, the distribution panel 45, and the grid 47 to each other. In addition, the main controller 44 may connect the above-described components to an auxiliary power source, such as the energy storage system 46 or an auxiliary power generation device (e.g., a diesel generator). For example, the main controller 44 may output power supplied from the combiner 42, to the distribution panel 45, the energy storage system 46, or the grid 47. In addition, the main controller 44 may output power supplied from the grid 47, to the distribution panel 45 or the energy storage system 46. In addition, the main controller 44 may output power supplied from the energy storage system 46, to the distribution panel 45.

The distribution panel 45 may electrically connect the main controller 44 to at least one load 43. Through this, the power supply system 40 may supply power generated by the photovoltaic power generation device 41 to the load 43 via the distribution panel 45.

By including the main controller 44, the power supply system 40 may integrate a plurality of energy storage systems 46 or auxiliary power generation devices into the power supply system 40. In addition, even in an off-grid environment where power is not stably supplied from the grid 47, the power supply system 40 may stably supply power to the load 43 such as a backup load.

The main controller 44 may perform control of voltage, current, or power output from or supplied to each component according to a state of the photovoltaic power generation device 41, the load 43, the energy storage system 46, or the grid 47. The main controller 44 may set an operation mode of the main controller 44, the photovoltaic power generation device 41, or the energy storage system 46 to a diagnosis mode, a driving mode, or the like.

In an embodiment, the power supply system 40 may further include a sub-panel (not shown) connected to the main controller 44 and separate from the distribution panel 45. Here, at least one backup load having a relatively high need for stable power supply among the loads 43 may be connected to the sub-panel. In addition, at least one non-backup load having a relatively low need for stable power supply among the loads 43 may be connected to the distribution panel 45.

The main controller 44 may electrically connect the combiner 42, the distribution panel 45, the energy storage system 46, the grid 47, and the sub-panel to each other. The main controller 44 may supply supplied power to at least one non-backup load via the distribution panel 45. In addition, the main controller 44 may supply the supplied power to the backup load via the sub-panel. Here, the supplied power may refer to power supplied from the combiner 42, the energy storage system 46, and/or the grid 47.

In addition, in an embodiment, the power supply system 40 may further include a sub-panel connected to the main controller 44 and separate from the distribution panel 45. In some embodiments, the grid 47 may be connected to the distribution panel 45 instead of being connected to the main controller 44. That is, the main controller 44 may electrically connect the combiner 42, the distribution panel 45, the energy storage system 46, and the sub-panel to each other. In addition, the distribution panel 45 may electrically connect the main controller 44, the non-backup load, and the grid 47 to each other.

For example, the power supply system 40 may be implemented by connecting the main controller 44 to the distribution panel 45. Here, the distribution panel 45 may be a device pre-installed to connect at least one load 43 to the grid 47. In some embodiments, the main controller 44 may be a device that connects the combiner 42 to the energy storage system 46.

Through this, even in an off-grid environment where the power supply system 40 cannot stably receive power from the grid 47, the power supply system 40 may stably supply power to the load 43 such as a backup load.

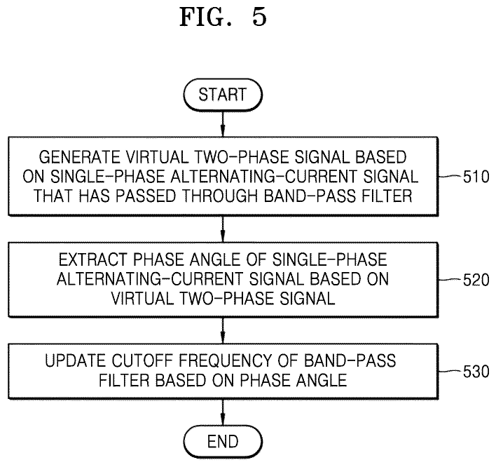

FIG. 5 is a flowchart of a method of controlling a phase-locked loop (PLL) circuit apparatus (hereinafter, referred to as an “apparatus”), according to an embodiment.

For example, the apparatus may be included in the device 12, the photovoltaic power generation device 21, the photovoltaic power generation device 31, or the photovoltaic power generation device 41. Alternatively, the apparatus may be included in the energy storage system 17, the energy storage system 35, or the energy storage system 46.

In operation 510, the apparatus may generate a virtual two-phase signal based on a single-phase AC signal that has passed through a band-pass filter (BPF).

According to an embodiment, the apparatus may include at least one BPF. For example, an input signal may pass through the at least one BPF. Here, the BPF may be an adaptive filter having a variable filter coefficient. For example, the filter coefficient included in the BPF may be associated with a cutoff frequency. That is, the apparatus may operate with at least one adaptive BPF capable of varying a cutoff frequency.

According to an embodiment, the apparatus may receive a single-phase AC signal as an input signal. The apparatus may operate by receiving a single-phase AC voltage. For example, a grid voltage may be the single-phase AC voltage received by the apparatus. As the single-phase AC voltage passes through the BPF, a DC component or noise included in the single-phase AC voltage may be reduced.

According to an embodiment, the apparatus may generate a virtual two-phase signal based on a signal obtained by passing the single-phase AC signal through an all-pass filter. Here, the virtual two-phase signal may be a signal artificially generated for convenience of calculation. The virtual two-phase signal may include an AC signal generated to have the same phase as the single-phase AC signal, and an AC signal generated to have a predetermined phase difference from the single-phase AC signal.

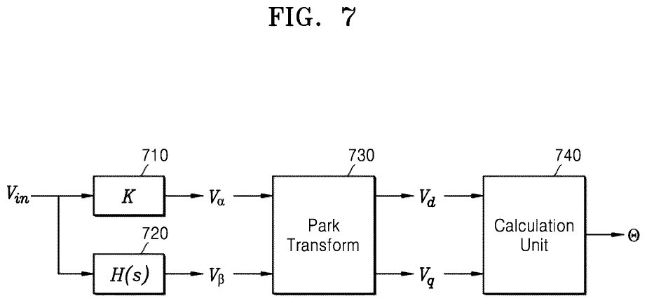

Here, the predetermined phase difference may refer to a phase difference of 90 degrees. That is, the virtual two-phase signal may include two AC signals arbitrarily generated to have a phase difference of 90 degrees. A detailed process of generating the virtual two-phase signal will be described below with reference to FIG. 7.

In operation 520, the apparatus may extract a phase angle of the single-phase AC signal based on the virtual two-phase signal.

According to an embodiment, the apparatus may extract the phase angle based on a calculation between an active component and a reactive component included in the virtual two-phase signal. A detailed process of extracting the phase angle will be described below with reference to FIG. 7.

According to an embodiment, the apparatus may generate a virtual DC signal based on the virtual two-phase signal. Here, the virtual DC signal may refer to a signal resulting from converting the virtual two-phase signal into two DC components through a predetermined calculation process. Here, the predetermined calculation process may refer to a process of converting an AC voltage as if it were a DC signal, through a matrix transformation on the virtual two-phase signal.

According to an embodiment, the apparatus may extract the phase angle through an operation on a complex plane for the virtual DC signal. Here, the virtual DC signal may include an active component and a reactive component. The apparatus may extract the phase angle through a calculation using the active component or the reactive component. The calculation using the active component or the reactive component may be an arctan calculation on the active component and the reactive component or an arcsin calculation on the reactive component. Here, the apparatus may determine whether a phase angle error exists by detecting the reactive component.

In operation 530, the apparatus may update the cutoff frequency of the BPF based on the extracted phase angle.

The apparatus according to an embodiment may detect a first frequency based on the phase angle. In addition, the apparatus may update the cutoff frequency to be synchronized with the detected first frequency. Here, the first frequency may be a frequency synchronized with a grid. That is, the apparatus may update the cutoff frequency of the BPF such that the cutoff frequency of the BPF is synchronized with the grid frequency. Thus, a system including the apparatus may be synchronized with the grid to stably transmit and receive power. Here, the system may correspond to a device, a photovoltaic power generation device, or an energy storage system including the apparatus.

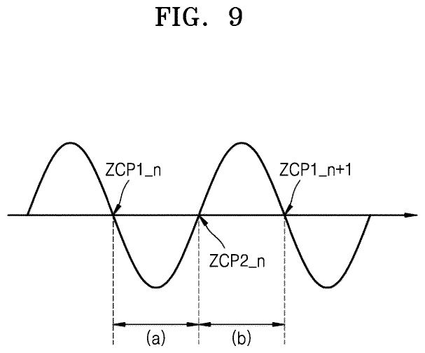

The apparatus according to an embodiment may detect the first frequency by using a plurality of zero-crossing points (ZCPs) of the single-phase AC signal, and update the cutoff frequency to be synchronized with the detected first frequency. Here, the ZCP may may refer to a point at which the phase of the AC signal transitions. A process of detecting the first frequency by using the ZCPs will be described below with reference to FIG. 9.

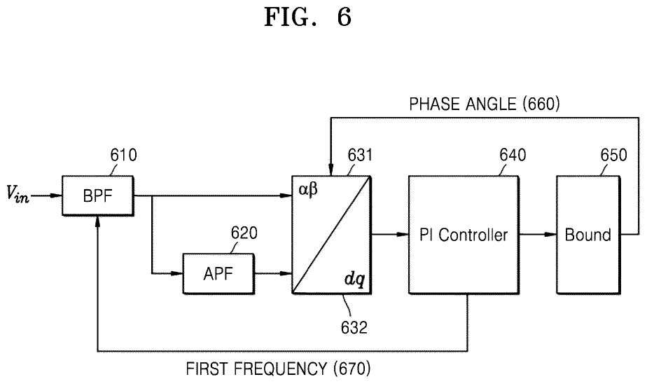

FIG. 6 is an example of a block diagram illustrating a method of controlling a PLL circuit, according to an embodiment.

According to an embodiment, the apparatus may generate a virtual two-phase signal based on a single-phase AC signal V_in that has passed through a BPF 610. In an embodiment, the virtual two-phase signal may be generated based on a signal that is output as the single-phase AC signal V_in passes through the BPF 610. That is, the virtual two-phase signal may be generated based on a first signal (not shown) that is a single-phase AC signal with reduced noise and DC offset.

In an embodiment, the apparatus may generate the virtual two-phase signal by using an all-pass filter 620. The virtual two-phase signal may be a signal that is output as the first signal passes through the all-pass filter 620. Here, the phase of the first signal may have its phase shifted while passing through the all-pass filter 620. That is, the all-pass filter 620 may correct the phase of the first signal. For example, while passing through the all-pass filter 620, the first signal may be adjusted such that its phase is delayed or advanced by the all-pass filter 620.

According to an embodiment, the apparatus may perform alpha-beta transformation 631 and d-q transformation 632 on the virtual two-phase signal. The apparatus may perform the alpha-beta transformation 631 on the virtual two-phase signal to generate a beta-axis voltage orthogonal to an alpha-axis voltage. Accordingly, the apparatus may obtain two-phase components of an alpha-axis and a beta-axis prior to the d-q transformation 632 for extracting a phase and a frequency.

According to an embodiment, the apparatus may perform the d-q transformation 632 on the alpha-axis voltage and the beta-axis voltage. The apparatus may perform the d-q transformation 632 to generate a d-axis component and a q-axis component. Here, the d-axis component may be a component corresponding to a DC component, and the q-axis component may be a component orthogonal to the d-axis component. Accordingly, the apparatus may detect a phase error based on the q-axis component. Here, when detecting the phase error, a fed-back phase angle 660 may be used, as will be described below.

According to an embodiment, by using a proportional-integral (PI) controller 640, the apparatus may adjust a phase error that is detected based on a signal generated by the d-q transformation 632, in particular, based on a q-axis component. This will be described below with reference to FIG. 7.

The apparatus may generate a compensation signal for reducing a frequency error, by using the PI controller 640. The compensation signal is a frequency estimate and may correspond to a first frequency 670. The first frequency 670 may be fed back to the BPF 610, and the apparatus may determine the cutoff frequency of the BPF 610 based on the first frequency 670.

According to an embodiment, the apparatus may process an output of the PI controller 640 by using a bound block 650. The bound block 650 may include a module configured to maintain a phase angle within a predetermined range. For example, when the phase angle input to the bound block 650 is greater than 2π, the apparatus may readjust the phase angle to start from 0. When the input phase angle is within a range of −2π and 2π, the apparatus may output the phase angle as is.

According to an embodiment, the phase angle 660 output from the bound block 650 may be fed back to the d-q transformation block 632. The apparatus may use the phase angle 660 fed back in this manner when calculating a phase error for the next cycle. Through this feedback loop, the apparatus may continuously track the phase of the input signal and maintain synchronization.

FIG. 7 is an example of a block diagram illustrating a method of extracting a phase angle, according to an embodiment.

According to an embodiment, the apparatus may generate the virtual two-phase signal based on the single-phase AC signal V_in that has passed through the BPF 610. First, the apparatus may adjust the scale of the single-phase AC signal V_in by using a gain block 710. The apparatus may generate a signal having an adjusted magnitude by adjusting the scale of the single-phase AC signal V_in according to a gain K.

In addition, the apparatus may adjust a phase response of the single-phase AC signal V_in by using an H(s) block 720. Here, the H(s) block 720 may perform the same operation as the all-pass filter 620 described above with reference to FIG. 6. That is, by using the H(s) block 720, the apparatus may adjust the phase response of the single-phase AC signal V_in to be delayed or advanced. Here, the signal whose phase response has been adjusted by using the H(s) block 720 may be a signal having a phase difference of 90 degrees with respect to the single-phase AC signal V_in.

According to an embodiment, the apparatus may generate an alpha-axis voltage based on the signal whose scale has been adjusted by using the gain block 710. In addition, the apparatus may generate a beta-axis voltage based on the signal whose phase response has been adjusted by using the H(s) block 720.

According to an embodiment, the apparatus may convert each of the alpha-axis and beta-axis components into a component of a rotating reference frame by using a Park transform unit 730. Here, the apparatus may perform a calculation based on Equation 1 below by using the Park transform unit 730.

$$( \begin{matrix}{V}_{d} \\ {V}_{q}\end{matrix} ) = ( \begin{matrix}cos ( θ ) & sin ( θ ) \\ - sin ( θ ) & cos ( θ )\end{matrix} ) ( \begin{matrix}{V}_{α} \\ {V}_{β}\end{matrix} ) \qquad [ Equation 1 ]$$

In Equation 1, θ may correspond to a phase angle of a signal to be estimated by the apparatus. Here, the phase angle may be a phase angle estimated internally by the apparatus, and may correspond to the phase angle 660 described above with reference to FIG. 6. The apparatus may calculate DC components of the rotating coordinate system by using Equation 1. Here, the DC components may be virtual values extracted for convenience of calculation. The DC components may include the d-axis component and the q-axis component orthogonal thereto described above with reference to FIG. 6.

By using a calculation unit 740, the apparatus according to an embodiment may extract the phase angle θ based on a calculation between an active component and a reactive component that are included in the virtual two-phase signal. Here, the active component may refer to the q-axis component, and the reactive component may refer to the d-axis component. That is, the apparatus may extract the phase angle θ through a calculation on a complex plane for the d-axis component and the q-axis component, by using the calculation unit 740. Here, the calculation unit 740 may perform a calculation based on Equation 2 or Equation 3 below.

$${θ}_{e r r} = {tan}^{- 1} ( \frac{{V}_{d}}{{V}_{q}} ) \qquad [ Equation 2 ]$$

$${θ}_{e r r} = {sin}^{- 1} ( {V}_{d} ) \qquad [ Equation 3 ]$$

In Equation 2 and Equation 3, θₑᵣᵣ may denote a phase angle error. The apparatus may determine whether the phase angle error calculated through Equation 2 or Equation 3 is close to zero. That is, by using Equation 2 or Equation 3, the apparatus may determine whether the finally extracted phase angle value accurately tracks the phase of the grid voltage.

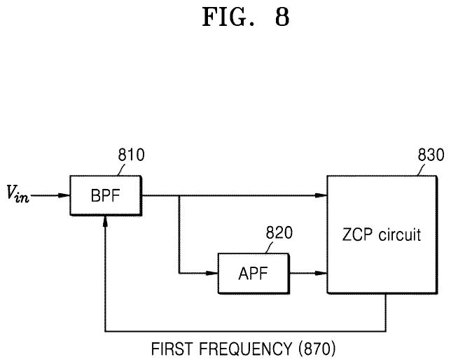

FIG. 8 is an example of a block diagram illustrating a method of controlling a PLL circuit, according to another embodiment.

In the following description of the method of controlling a PLL circuit, redundant descriptions provided above with reference to FIG. 6 will be omitted.

According to an embodiment, the apparatus may obtain a signal with reduced DC components and noise based on the single-phase AC signal V_in that has passed through a BPF 810. The apparatus may generate a virtual two-phase signal by using an all-pass filter 820. Here, the BPF 810 and the all-pass filter 820 may be the same as the BPF 610 and the all-pass filter 620, respectively.

According to an embodiment, the apparatus may generate a first frequency 870 by using a ZCP circuit 830. The ZCP circuit 830 may be a circuit configured to detect a ZCP of an input signal. That is, by using the ZCP circuit, the apparatus may calculate a frequency estimate for the signal that has passed through the filter.

Here, the apparatus may detect a ZCP of the single-phase AC signal that has passed through the BPF 810, and calculate a frequency estimate based thereon. In addition, the apparatus may use the single-phase AC signal that has passed through the all-pass filter 620 as auxiliary information to reduce errors that may occur when detecting the ZCP. Here, the apparatus may calculate the frequency estimate by using a plurality of ZCPs. A method of calculating the frequency estimate will be described below with reference to FIG. 9.

The frequency estimate for the signal that has passed through the filter may correspond to the first frequency 870. The first frequency 870 may be fed back to the BPF 810. In addition, the apparatus may determine the cutoff frequency of the BPF 810 based on the first frequency 870. That is, the apparatus may update the cutoff frequency of the BPF 810 to be synchronized with the first frequency 870. Thus, the apparatus may calculate a frequency estimate even without a separate calculation process for detecting a phase angle. In addition, the apparatus may maintain synchronization with the input signal based on the calculated frequency estimate.

FIG. 9 illustrates an example of a method of detecting a first frequency by using ZCPs, according to an embodiment.

According to an embodiment, the apparatus may detect ZCPs of an AC signal input to the ZCP circuit 830, and detect a first frequency based thereon. Here, the AC signal input to the ZCP circuit 830 may be an AC signal that has passed through only the BPF 810, or may be an AC signal that has sequentially passed through the BPF 810 and the all-pass filter 820.

According to an embodiment, the apparatus may recognize an interval in which the phase of the AC signal transitions. The apparatus may distinctively detect a transition from a positive (+) signal to a negative (−) signal and a transition from a negative (−) signal to a positive (+) signal. Referring to FIG. 9, the apparatus may designate points of transition from a positive (+) signal to a negative (−) signal as ZCP1, and points of transition from a negative (−) signal to a positive (+) signal as ZCP2.

According to an embodiment, the apparatus may detect a phase transition of an AC voltage signal to measure the frequency of the AC voltage signal. To this end, the apparatus may sample the AC voltage signal by converting it into digital values at regular time intervals. Here, the regular time intervals for converting the AC voltage signal may vary depending on a preset number of samples. The preset number of samples may be based on a preset sampling frequency. For example, when the preset sampling frequency is 25 kHz, the preset number of samples may correspond to 25,000 samples per second.

Here, the apparatus may calculate the number of samples (a) for an interval from ZCP1_n to ZCP2_n. In addition, the apparatus may calculate the number of samples (b) for an interval from ZCP2_n to ZCP1_n+1. The apparatus may detect the frequency of the AC voltage signal based on the sum of the number of samples (a) and the number of samples (b).

Here, the apparatus may detect the frequency of the AC voltage signal by dividing the preset sampling frequency by the sum of the numbers of samples. That is, the apparatus may detect the first frequency by calculating the sum of the number of samples (a) and the number of samples (b) and then dividing the preset sampling frequency by the sum. Accordingly, the apparatus may detect the frequency even through a relatively simple calculation process.

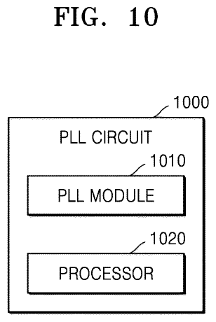

FIG. 10 is a block diagram of a PLL circuit according to an embodiment.

Referring to FIG. 10, a PLL circuit 1000 may include a PLL module 1010 and a processor 1020. Here, the PLL circuit 1000 may correspond to the apparatus described above with reference to FIGS. 5 to 9.

Because FIG. 10 illustrates only components of the PLL circuit 1000 that are related to the present embodiments, it is apparent to those skilled in the art that other general-purpose components may be further included in addition to the components illustrated in FIG. 10.

The PLL circuit 1000 according to an embodiment may include the PLL module 1010 and the processor 1020 configured to update a cutoff frequency of a BPF based on a phase angle. The PLL module 1010 may include a BPF configured to pass a single-phase AC signal, and a PI controller configured to extract a phase angle of the single-phase AC signal based on a virtual two-phase signal. In some embodiments, the PLL module 1010 may further include an all-pass filter configured to generate a virtual two-phase signal based on the single-phase AC signal that has passed through the BPF.

According to an embodiment, the processor 1020 may control the overall operation of the PLL circuit 1000. The processor 1020 may correspond to an operating entity that controls the overall operation of the PLL circuit 1000 according to a control signal from the control unit described above with reference to FIG. 1. The processor 1020 may control at least a part of operations of the apparatus described above with reference to FIGS. 5 to 9. For example, the processor 1020 may detect a first frequency and update the cutoff frequency to be synchronized with the detected first frequency.

The processor 1020 may detect a plurality of ZCPs of the single-phase AC signal. The processor 1020 may detect the first frequency by using the plurality of detected ZCPs. In addition, the processor 1020 may update the cutoff frequency such that the detected first frequency and the cutoff frequency are synchronized with each other.

Specific examples of the operations of the processor 1020 and each component included in the PLL module 1010 are the same as described above with reference to FIGS. 5 to 9. Therefore, a detailed description of the operations of the PLL module 1010 and the processor 1020 will be omitted hereinafter.

Meanwhile, an embodiment of the present disclosure may be implemented as a computer program that may be executed through various components on a computer, and such a computer program may be recorded in a computer-readable medium. In this case, the medium may include, but is not limited to, a magnetic medium, such as a hard disk, a floppy disk, or a magnetic tape, an optical recording medium, such as a compact disc read-only memory (CD-ROM) or a digital video disc (DVD), a magneto-optical medium, such as a magneto-optical disk, and a hardware device specially configured to store and execute program instructions, such as read-only memory (ROM), random-access memory (RAM), or flash memory.

In addition, the computer program may be specially designed and configured for the present disclosure or may be well-known to and usable by those skilled in the art of computer software. Examples of the computer program may include not only machine code, such as code made by a compiler, but also high-level language code that is executable by a computer by using an interpreter or the like.

According to an embodiment, the method according to various embodiments of the present disclosure may be included in a computer program product and provided. The computer program product may be traded as a commodity between sellers and buyers. The computer program product may be distributed in the form of a machine-readable storage medium (e.g., a CD-ROM), or may be distributed online (e.g., downloaded or uploaded) through an application store (e.g., Play Store™) or directly between two user devices. In a case of online distribution, at least a portion of the computer program product may be temporarily stored in a machine-readable storage medium such as a manufacturer's server, an application store's server, or a memory of a relay server.

The operations of the methods according to the present disclosure may be performed in any suitable order unless otherwise indicated herein or otherwise clearly contradicted by context. The present disclosure is not limited to the described order of the operations. The use of any and all examples, or exemplary language (e.g., ‘and the like’) provided herein, is intended merely to better illuminate the present disclosure and does not pose a limitation on the scope of the present disclosure unless otherwise claimed. Also, numerous modifications and adaptations will be readily apparent to those skilled in the art without departing from the spirit and scope of the present disclosure.

Therefore, the spirit of the present disclosure should not be limited to the above-described embodiments, and all modifications and variations which may be derived from the meanings, scopes and equivalents of the claims should be construed as falling within the scope of the present disclosure.

According to the present invention, by adding a BPF to a PLL, it is possible to reduce noise or DC offset during AC voltage sensing.

Effects of the present disclosure are not limited to the foregoing, and other unmentioned effects would be clearly understood by those skilled in the art from the above description.

What is claimed is:

1. A method of controlling a phase-locked loop (PLL) circuit, the method comprising:
generating a virtual two-phase signal based on a single-phase alternating-current signal that has passed through a band-pass filter;
extracting a phase angle of the single-phase alternating-current signal based on the virtual two-phase signal; and
updating a cutoff frequency of the band-pass filter based on the phase angle.

2. The method of claim 1, wherein the generating comprises generating the virtual two-phase signal based on a signal obtained by passing the single-phase alternating-current signal through an all-pass filter.

3. The method of claim 1, wherein the generating comprises generating the virtual two-phase signal to be orthogonal to the single-phase alternating-current signal.

4. The method of claim 1, wherein the extracting comprises extracting the phase angle based on a calculation between an active component and a reactive component that are included in the virtual two-phase signal.

5. The method of claim 4, wherein the extracting further comprises:
generating a virtual direct-current signal based on the virtual two-phase signal; and
extracting the phase angle based on a calculation on a complex plane for the virtual direct-current signal.

6. The method of claim 1, wherein the updating comprises:
detecting a first frequency based on the phase angle; and
updating the cutoff frequency such that the cutoff frequency is synchronized with the first frequency.

7. The method of claim 6, wherein the updating further comprises:
detecting the first frequency by using a plurality of zero-crossing points (ZCPs) of the single-phase alternating-current signal; and
updating the cutoff frequency such that the cutoff frequency is synchronized with the first frequency.

8. A phase-locked loop (PLL) circuit comprising:
a band-pass filter configured to pass a single-phase alternating-current signal;
a proportional-integral (PI) controller configured to extract a phase angle of the single-phase alternating-current signal based on a virtual two-phase signal; and
a processor configured to update a cutoff frequency of the band-pass filter based on the phase angle.

9. The PLL circuit of claim 8, further comprising an all-pass filter configured to generate the virtual two-phase signal based on the single-phase alternating-current signal that has passed through the band-pass filter.

10. The PLL circuit of claim 9, wherein the all-pass filter is further configured to generate the virtual two-phase signal to be orthogonal to the single-phase alternating-current signal.

11. The PLL circuit of claim 8, wherein the PI controller is further configured to extract the phase angle based on a calculation on a complex plane for the virtual two-phase signal.

12. The PLL circuit of claim 11, wherein the PI controller is further configured to generate a virtual direct-current signal based on the virtual two-phase signal, and extract the phase angle based on a calculation on a complex plane for the virtual direct-current signal.

13. The PLL circuit of claim 8, wherein the processor is further configured to detect a first frequency based on the phase angle, and update the cutoff frequency such that the cutoff frequency is synchronized with the first frequency.

14. The PLL circuit of claim 13, wherein the processor is further configured to detect a plurality of zero-crossing points (ZCPs) of the single-phase alternating-current signal, detect the first frequency by using the plurality of ZCPs, and update the cutoff frequency such that the cutoff frequency is synchronized with the first frequency.

15. A computer-readable recording medium having recorded thereon a program for causing a computer to execute the method of claim 1.
